(19) United States
(12) Patent Application Publication
(10) Pub. No.: US 2025/0319551 A1
(43) Pub. Date: Oct. 16, 2025

(54) LASER PROCESSING APPARATUS AND LASER PROCESSING METHOD

(71) Applicant: Samsung Electronics Co., Ltd., Suwon-si (KR)

(72) Inventor: Narae HAN, Suwon-si (KR)

(73) Assignee: Samsung Electronics Co., Ltd., Suwon-si (KR)

(21) Appl. No.: 19/078,954

(22) Filed: Mar. 13, 2025

(30) Foreign Application Priority Data
Apr. 16, 2024 (KR) 10-2024-0050555

(51) Int. Cl. B23K 26/364; B23K 26/06; B23K 26/067; B23K 26/073; B23K 26/08; B23K 26/402; B23K 103/00; G02B 19/00; G02B 27/09; G02B 27/10; G02B 27/28; H01L 21/67

(52) U.S. Cl. CPC B23K 26/364; B23K 26/0665; B23K 26/0676; B23K 26/0734; B23K 26/08; B23K 26/402; G02B 19/0009; G02B 19/0047; G02B 27/0927; G02B 27/106; G02B 27/1086; G02B 27/288; H01L 21/67092; B23K 2103/56

(57) ABSTRACT

A laser processing apparatus includes a stage to support a substrate, a laser light source to generate a source laser beam, a first beam divider to divide the source laser beam into first and second laser beams in a first horizontal direction, a second beam divider to divide the first laser beams into a plurality of first laser sub-beams in a second horizontal direction and to divide the second laser beam into a plurality of second laser sub-beams in the second horizontal direction, and a condensing lens to condense the plurality of first laser sub-beams into a plurality of first laser branch beams that are spaced apart along a first scan line on the substrate and to condense the plurality of second laser sub-beams into a plurality of second laser branch beams spaced apart along a second scan line parallel with the first scan line on the substrate.

### CROSS REFERENCE TO RELATED APPLICATION

This U.S. non-provisional application claims priority under 35 U.S.C. § 119 to Korean Patent Application No. 10-2024-0050555, filed on Apr. 16, 2024, in the Korean Intellectual Property Office (KIPO), the contents of which are herein incorporated by reference in their entirety.

### BACKGROUND

Example embodiments relate to a laser processing apparatus and a laser processing method.

A laser grooving process may be a scribing process that forms a groove by irradiating a laser on a surface of substrate such as a silicon wafer or a pattern formed on the substrate. In the laser grooving process, a plurality of laser beams may be irradiated to form a single line of focuses on the substrate surface and then, the substrate may be scanned to form grooves in the substrate surface, thereby dicing a wafer or etching a pattern on the wafer. Some factors that determine productivity in the laser grooving process may include a speed of moving the wafer and/or a number of scans. It may be desirable to reduce the number of scans to improve productivity.

### SUMMARY

Some example embodiments provide a laser processing apparatus that may improve productivity.

Some example embodiments provide a laser processing method using the above laser processing apparatus.

According to some example embodiments, a laser processing apparatus includes a stage configured to support a substrate; a laser light source configured to generate a source laser beam; a first beam divider configured to divide the source laser beam into a first laser beam and a second laser beam in a first horizontal direction; a second beam divider configured to divide the first laser beam into a plurality of first laser sub-beams in a second horizontal direction and to divide the second laser beam into a plurality of second laser sub-beams in the second horizontal direction; a condensing lens configured to condense the plurality of first laser sub-beams into a plurality of first laser branch beams that are spaced apart along a first scan line on the substrate and to condense the plurality of second laser sub-beams into a plurality of second laser branch beams that are spaced apart along a second scan line parallel with the first scan line on the substrate; and a driving portion configured to move the plurality of first laser branch beams and the plurality of second laser branch beams relative to the substrate in the second horizontal direction.

According to some example embodiments, a laser processing apparatus includes a stage configured to support a substrate; a laser irradiator configured to converge and irradiate a plurality of first laser branch beams in a first scan line on the substrate and a plurality of second laser branch beams in a second scan line on the substrate, the first scan line and second scan line being spaced apart in a first horizontal direction; and a driving portion configured to move the stage or the laser irradiator and to move the plurality of first laser branch beams and the plurality of second laser branch beams with respect to the substrate in a second horizontal direction different from the first horizontal direction. The laser irradiator includes a laser light source configured to generate a source laser beam; a mode converter configured to convert the source laser beam into a cylindrical vector beam; a polarization filter configured to polarize the cylindrical vector beam to form a double-o shaped beam in which a first laser beam and a second laser beam are arranged adjacent to each other in the first horizontal direction; a diffractive optical element configured to divide the first laser beam into a plurality of first laser sub-beams in the second horizontal direction and to divide the second laser beam into a plurality of second laser sub-beams in the second horizontal direction; and a condensing lens in optical paths of the plurality of first laser sub-beams and the plurality of second laser sub-beams, the condensing lens being configured to condense the plurality of first laser sub-beams into the plurality of first laser branch beams and condense the plurality of second laser sub-beams into the plurality second laser branch beams on the substrate.

According to some example embodiments, a laser processing method includes supporting a substrate on a stage, obtaining a cylindrical vector beam; polarizing the cylindrical vector beam using a polarization filter to form a double-o shaped beam in which a first laser beam and a second laser beam are arranged adjacent to each other in a first horizontal direction; dividing the first laser beam into a plurality of first laser sub-beams in a second horizontal direction and dividing the second laser beam into a plurality of second laser sub-beams in the second horizontal direction; condensing, using a condensing lens, the plurality of first laser sub-beams into a plurality of first laser branch beams in a first scan line and condensing the plurality of second laser sub-beams into a plurality of second laser branch beams in a second scan line, the plurality of first laser branch beams and the plurality of second laser sub-beams being spaced apart in the first horizontal direction on the substrate; and scanning the plurality of first laser branch beams along the first scan line on the substrate and scanning the plurality of second laser branch beams along the second scan line on the substrate.

According to some example embodiments, in a laser processing method, a substrate is supported on a stage. A cylindrical vector beam is obtained. The cylindrical vector beam is polarized using a polarization filter to form a double-o shaped beam in which a first laser beam and a second laser beam are arranged adjacent to each other in a first horizontal direction. The first laser beam is divided into a plurality of first laser sub-beams in a second horizontal direction and the second laser beam is divided into a plurality of second laser sub-beams in the second horizontal direction. The plurality of first laser sub-beams are condensed, using a condensing lens, into a plurality of first laser branch beams in a first scan line and the plurality of second laser sub-beams are condensed, using the condensing lens, into a plurality of second laser branch beams in a second scan line, the plurality of first laser branch beams and the plurality of second laser sub-beams are spaced apart in the first horizontal direction on the substrate. The plurality of first laser branch beams are scanned along the first scan line on the substrate and the plurality of second laser branch beams are scanned along the second scan line on the substrate.

According to some example embodiments, obtaining the cylindrical vector beam may include generating a source laser beam, and converting the source laser beam into the cylindrical vector beam using a mode converter.

According to some example embodiments, the laser processing method may further include expanding the cylindrical vector beam using a beam expander, wherein the beam expander is in an optical path of the cylindrical vector beam, and the beam expander is configured to adjust a spacing in the first horizontal direction between corresponding laser branch beams of the plurality of first laser branch beams and the plurality of second laser branch beams.

According to some example embodiments, the laser processing method may further include modulating phases of the plurality of first laser sub-beams and the plurality of second laser sub-beams using an electro-optic modulator arranged in optical paths of the plurality of first laser sub-beams and the plurality of second laser sub-beams.

According to some example embodiments, scanning the plurality of first laser branch beams and the plurality of second laser branch beams may include moving the stage in the second horizontal direction different from the first horizontal direction.

According to some example embodiments, a laser processing apparatus may include a first beam divider configured to convert a source laser beam emitted from a laser light source as a single light source into a first laser beam and a second laser beam in a first horizontal direction, a second beam divider configured to divide the first laser beam into a plurality of first laser sub-beams in a second horizontal direction and to divide the second laser beam into a plurality of second laser sub-beams in the second horizontal direction, and a condensing lens to condense the plurality of first laser sub-beams into the plurality of first laser branch beams and condense the plurality of second laser sub-beams into the plurality of second laser branch beams on a substrate. The plurality of first laser branch beams are along a first scan line and the plurality of second laser branch beams are along a second scan line spaced apart from the first scan line in the first horizontal direction on a surface of a substrate. In addition, the laser processing apparatus may further include an index adjuster configured to adjust a spacing distance in the first horizontal direction between the first and second laser branch beams.

The plurality of first laser branch beams and the plurality of second laser branch beams may be simultaneously scanned along two first and second scan lines on the substrate. A distance between spot positions of the first and second laser branch beams may be adjusted according to a size of a die that is to be diced from the wafer. The plurality of first laser branch beams and the plurality of second laser branch beams may be focused by the condensing lens.

Accordingly, the plurality of first laser branch beams and the plurality of second laser branch beams may be simultaneously scanned while tracking a surface height in real time along two adjacent scan lines and with minimal increase in a size of the optical system. Thus, a productivity of a laser grooving process may be improved. Further, the distance between corresponding one of the first and second laser branch beams may be adjusted optically with relative ease.

### BRIEF DESCRIPTION OF THE DRAWINGS

Example embodiments will be more clearly understood from the following detailed description taken in conjunction with the accompanying drawings. FIGS. 1 to 12 represent some non-limiting example embodiments as described herein.

FIG. 1 is a perspective view illustrating a laser processing apparatus, according to some example embodiments.

FIGS. 2 and 3 are block diagrams illustrating a laser irradiator of FIG. 1, according to some example embodiments.

FIGS. 4A illustrates the source laser beam generated by the laser light source of FIGS. 2 and 3.

FIG. 4B illustrates a graph that indicates the intensity distribution of the laser beam emitted from the laser light source of FIGS. 2 and 3.

FIG. 4C illustrates the cylindrical vector beam laser converted and emitted by the mode converter of FIGS. 2 and 3.

FIG. 4D illustrates a graph that indicates the intensity distribution of the laser beams emitted from the mode converter of FIGS. 2 and 3.

FIG. 5 is a cross-sectional view illustrating a beam expander that expands a diameter of the converted laser beam, according to some example embodiments.

FIG. 6 is a diagram illustrating a shape and polarization of a filtered beam of a cylindrical incident beam having azimuth polarization after passing through a polarization filter, according to some example embodiments.

FIG. 7 is a diagram illustrating a shape and polarization of a filtered beam of a cylindrical incident beam having radial polarization after passing through a polarization filter, according to some example embodiments.

FIG. 8A is a cross-sectional view illustrating first laser sub-beams split from a first laser beam by a diffractive optical element, according to some example embodiments.

FIG. 8B is a cross-sectional view illustrating second laser sub-beams split from a second laser beam by a diffractive optical element, according to some example embodiments.

FIG. 9 is a perspective view illustrating a first beam divider, a second beam divider, and a condensing lens of FIG. 2, according to some example embodiments.

FIG. 10 is a flow chart illustrating a laser processing method, according to some example embodiments.

FIG. 11 is a plan view illustrating two scan lines on a wafer along which a plurality of first laser branch beams and a plurality of second laser branch beams are scanned.

FIG. 12 is a perspective view illustrating the plurality of first laser branch beams and the plurality of second laser branch beams irradiated along two scan lines in FIG. 11.

### DETAILED DESCRIPTION

Hereinafter, example embodiments will be explained with reference to the accompanying drawings.

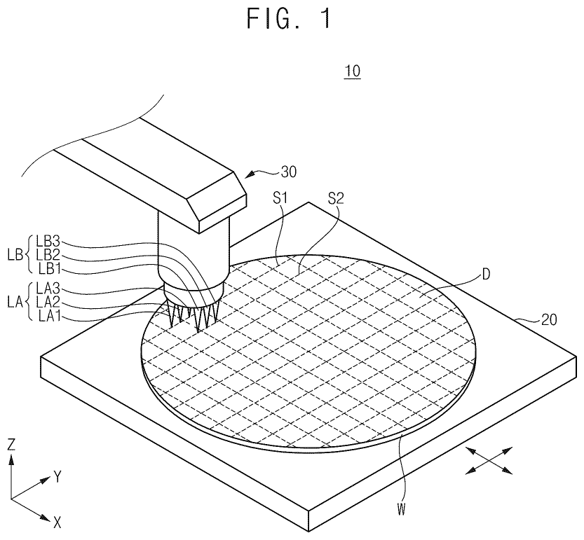

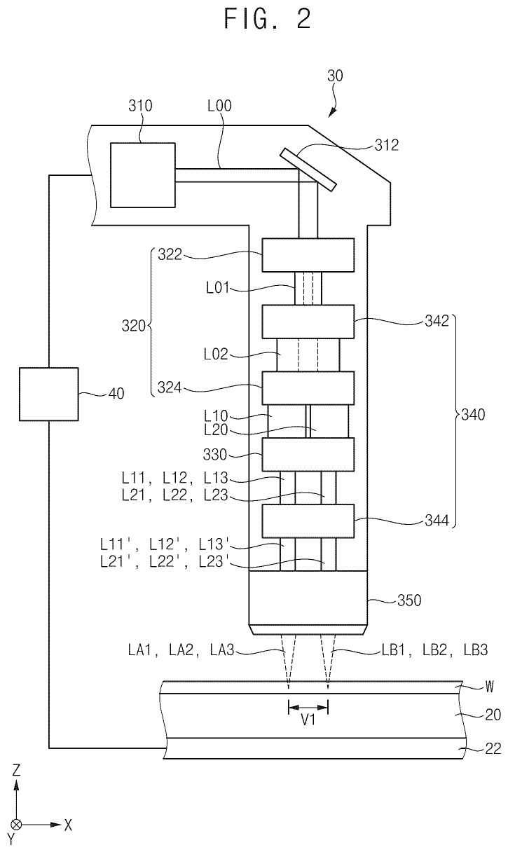

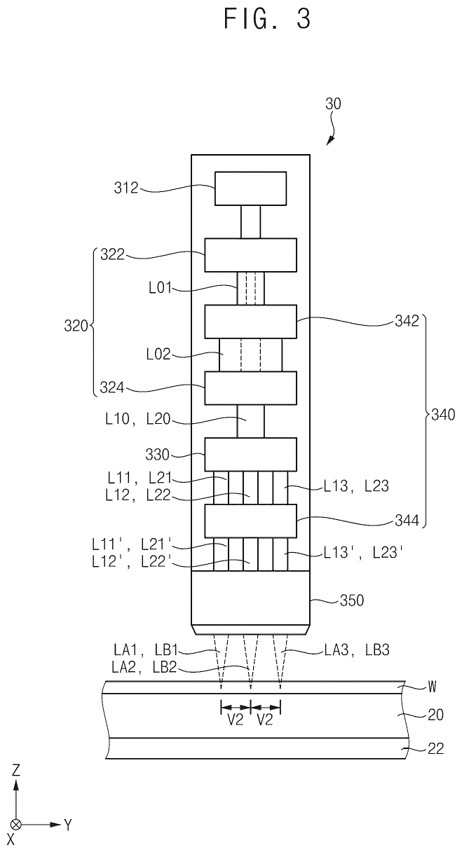

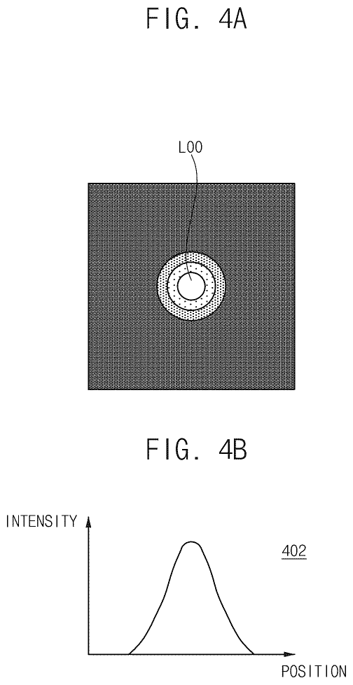

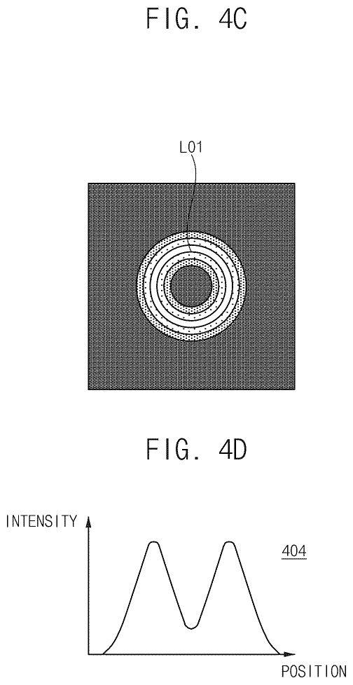

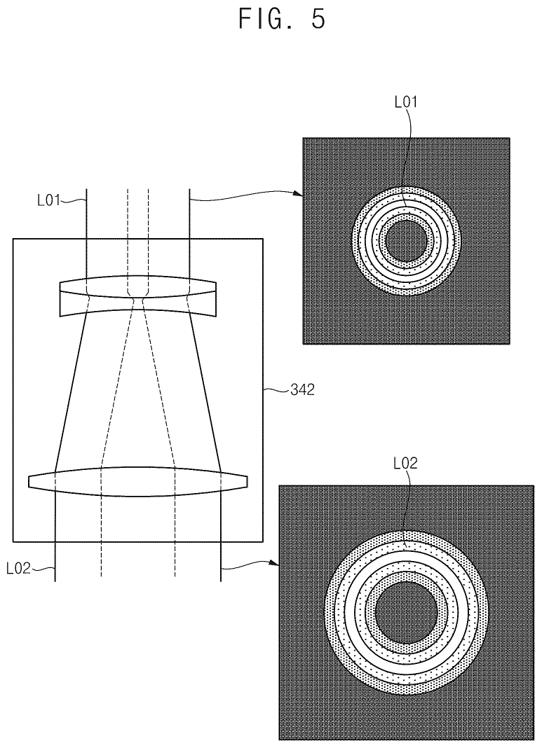

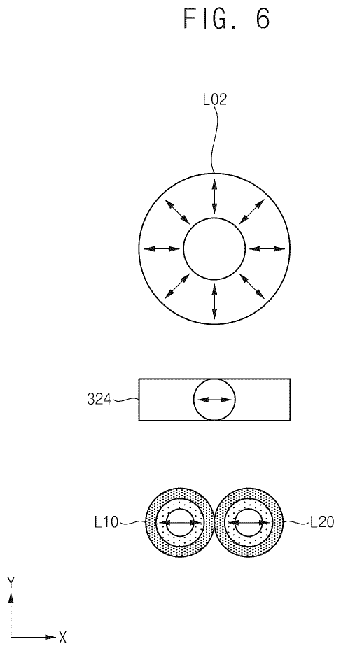

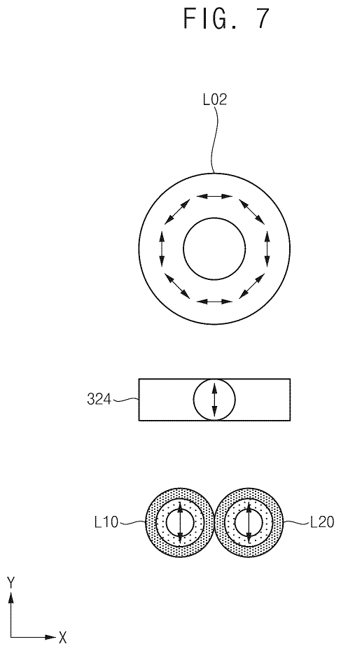

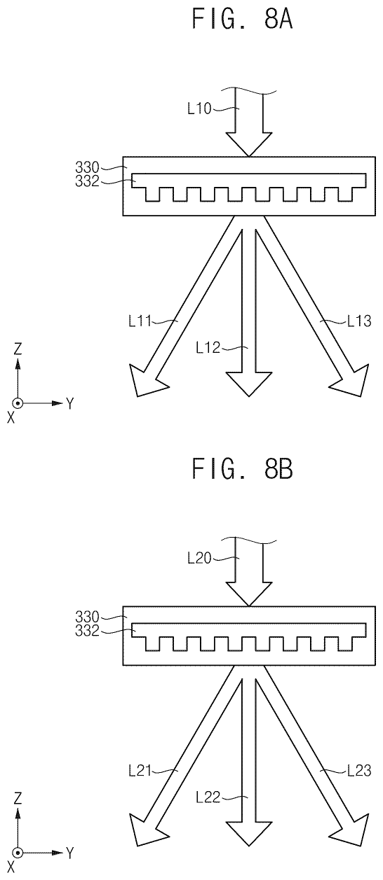

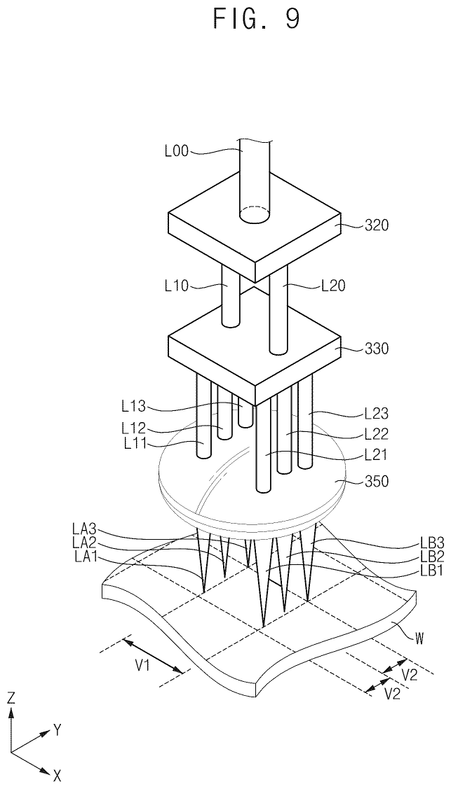

FIG. 1 is a perspective view illustrating a laser processing apparatus, according to some example embodiments. FIGS. 2 and 3 are block diagrams illustrating a laser irradiator of FIG. 1, according to some example embodiments. FIGS. 4A illustrates the source laser beam generated by the laser light source of FIGS. 2 and 3. FIG. 4B illustrates a graph that indicates the intensity distribution of the laser beam emitted from the laser light source of FIGS. 2 and 3. FIG. 4C illustrates the cylindrical vector beam laser converted and emitted by the mode converter of FIGS. 2 and 3. FIG. 4D illustrates a graph that indicates the intensity distribution of the laser beams emitted from the mode converter of FIGS. 2 and 3. FIG. 5 is a cross-sectional view illustrating a beam expander that expands a diameter of the converted laser beam, according to some example embodiments. FIG. 6 is a diagram illustrating a shape and polarization of a filtered beam of a cylindrical incident beam having azimuth polarization after passing through a polarization filter, according to some example embodiments. FIG. 7 is a diagram illustrating a shape and polarization of a filtered beam of a cylindrical incident beam having radial polarization after passing through a polarization filter, according to some example embodiments. FIG. 8A is a cross-sectional view illustrating first laser sub-beams split from a first laser beam by a diffractive optical element, and FIG. 8B is a cross-sectional view illustrating second laser sub-beams split from a second laser beam by a diffractive optical element, according to some example embodiments. FIG. 9 is a perspective view illustrating a first beam divider, a second beam divider, and a condensing lens of FIG. 2, according to some example embodiments. For sake of simplicity/clarity of illustration, certain components of FIGS. 2 and 3 have been omitted in FIG. 9.

Referring to FIGS. 1 to 9, a laser processing apparatus 10 may include a stage 20 and a laser irradiator 30. In addition or alternatively, the laser processing apparatus 10 may further include a controller 40 connected to the stage 20 and the laser irradiator 30 to control their operations.

In some example embodiments, the controller 40 may be connected to the stage 20 and/or the laser irradiator 30 using a wired connection. Alternatively or additionally, the controller 40 may be wirelessly connected to the stage 20 and/or the laser irradiator 30. In some example embodiments, the controller 40 may be or include a processor, and/or may be or a laptop, a desktop, a tablet, and/or a smartphone. However, example embodiments are not limited thereto.

In some example embodiments, the laser processing apparatus 10 may irradiate a plurality of first laser branch beams LA (individually, referred to as LA1, LA2, LA3) and a plurality of second laser branch beams LB (individually, referred to as LB1, LB2, LB3) onto a surface of a substrate W such as a wafer or a pattern formed on the substrate W to form grooves. The laser processing apparatus 10 may, simultaneously, sequentially, or in any desired order, scan the plurality of first laser branch beams LA and the plurality of second laser branch beams LB along two scan lines S1 and S2 on the substrate W. Thus, the grooves may be formed on the surface of the substrate W or the pattern along the two scan lines S1 and S2.

The laser processing apparatus 10 may further include a driving portion configured to move the plurality of first laser branch beams LA and the plurality of second laser branch beams LB relative to the substrate W. The driving portion may include a stage driver 22 configured to move the stage 20 along three orthogonal axes, such as along X, Y, and Z axes.

In some example embodiments, the stage 20 may be a movable table or any other device (e.g., electrostatic chuck or similar) that supports or secures the substrate W and is able to move in at least one direction. The stage 20 may be movable in X and Y directions on the stage driver 22. The stage driver 22 may include a stage drive mechanism for moving the stage 20, and the stage driver 22 may move the stage 20 in the X and Y directions in response to a control signal from the controller 40. A moving speed of the stage 20 may be adjustable by the controller 40.

In addition, the driving portion may further include a laser head driver for moving the laser irradiator 30 in the X, Y, and Z axes. For example, the laser head driver may move an optical system of the laser irradiator 30 in the X, Y, and Z directions. Alternatively or in addition, the laser head driver may move the laser irradiator 30 in the Z direction, and the stage driver 22 may move the wafer W in the X and Y directions and may rotate the stage 20 about the center of the wafer W.

For example, the substrate W may include a silicon wafer (Si Wafer), a silicon carbide wafer (SiC Wafer), a gallium arsenide wafer (GaAs Wafer), or a silicon single crystal wafer (Si-Single Crystal Wafer). A thickness of the substrate W may be within a range of 50 μm (or about 50 μm) to 850 μm (or about 850 μm).

As illustrated in FIGS. 2, 3 and 9, the laser irradiator 30 may include a laser light source 310 to generate a source laser beam L00, a beam splitter 312 to split or redirect the source laser beam L00 to a first beam divider 320 that may divide the source laser beam L00 into first and second laser beams L10, L20 in a first horizontal direction (X direction), a second beam divider 330 to divide the first laser beam L10 into a plurality of first laser sub-beams L11, L12, L13 in a second horizontal direction (Y direction) and to divide the second laser beam L20 into a plurality of second laser sub-beams L21, L22, L23 in the second horizontal direction (Y direction), and a condensing lens 350 to condense the plurality of first laser sub-beams L11, L12, L13 into a plurality of first laser branch beams LA1, LA2, LA3 and the plurality of second laser sub-beams L21, L22, L23 into a plurality of second laser branch beams LB1, LB2, LB3 at the surface of the substrate W. The first beam divider 320 may include a mode converter 322 and a polarization filter 324. The laser irradiator 30 may further include an index adjuster 340 to adjust a spacing distance V1 in the first horizontal direction (X direction) between the corresponding ones of the first and second laser branch beams. The index adjuster 340 may include at least one of a beam expander 342 and an optical modulator 344.

In particular, the laser light source 310 may emit the source laser beam L00 as a single light source. The source laser beam L00 may have a wavelength band having transparency to the substrate W, which is an object to be processed. The wavelength band may be within a wavelength range of 550 nm or less. The laser light source 310 may emit a pulsed laser beam. However, in some example embodiments, a continuous wave laser beam may be emitted depending on a type of a processing operation. The source laser beam L00 may be an ultrashort pulse laser beam having a pulse width of 1 μs or less, for example, on the order of picoseconds or femtoseconds.

The laser light source 310 may include a solid medium for passing the laser beam. Properties of the laser beam may vary depending on the solid medium. For example, the solid medium may include be ytterbium yttrium aluminum garnet compound (Yb:YAG), neodymium yttrium aluminum garnet compound (Nd:YAG), neodymium yttrium orthovanadate compound (Nd:YVO4), aluminum gallium arsenide compound, aluminum gallium indium compound (AlGaInP), gallium nitride compound (GaN), neodymium optical fiber (Nd-Fiber), sapphire, etc.

The mode converter 322 may convert the source laser beam L00 into a cylindrical vector beam (CVB) L01. The mode converter 322 may be installed inside the laser head or on an optical path of the source laser beam L00 after the laser head. The mode converter 322 may convert the source laser beam L00 generated by the laser light source 310 into a high-order mode laser beam. The mode converter 322 may convert a shape of a laser beam incident thereon into a donut shape (or a single-o shape) with minimal changes to the characteristics of the incident laser beam. For example, the mode converter 322 may convert a mode of the source laser beam L00 by using birefringence, using a dichroic material, or using an interferometer.

As illustrated in FIGS. 4A and 4C, the source laser beam L00 generated by the laser light source 310 may include a Gaussian beam (or Gaussian-shaped beam having a Gaussian-shaped spot), and the cylindrical vector beam laser L01 converted and emitted by the mode converter 322 may have a donut laser mode (or single-o shaped laser mode).

The beam expander 342 may be provided in the optical path of the cylindrical vector beam L01 and may expand the cylindrical vector beam L01. An expanded laser beam L02 expanded by the beam expander 342 may be incident on the polarization filter 324. The beam expander 342 may expand a diameter of a collimated input beam (e.g., vector beam L01) and emit a collimated output beam (e.g., laser beam L02) having a relatively larger diameter. FIG. 4B illustrates a graph 402 that indicates the intensity distribution of the laser beam emitted from the laser light source 310. As depicted, the intensity distribution is a bell shaped curve that indicates that the intensity distribution reduces as the radial distance from center of the laser beam increases. FIG. 4D illustrates a graph 404 that indicates the intensity distribution of the laser beams emitted from the mode converter 322. As depicted, the intensity distribution is low around the center of the laser beam and increases in the radially outward direction and then decreases again. Two intensity peaks are observed around midway to the end of the laser beam, at which the intensity of the laser beam is the highest.

As illustrated in FIG. 5, the beam expander 342 may include a combination (or system) of a plurality of lenses. The beam expander 342 may adjust a beam size while maintaining the same or similar output value. The spacing distance V1 in the first horizontal direction (X direction) between the first and second laser branch beams LA and LB may be determined according to the diameter of the laser beam L02 expanded by the beam expander 342. For example, the diameter or the full-width at half max (FWHM) of the laser beam L02 expanded by the beam expander 342 may determine the distance between two scan lines S1 and S2 on the substrate W.

The polarization filter 324 may polarize the expanded cylindrical vector beam L02 to form a ∞ double-o shaped beam in which two beams L10 and L20 are arranged adjacent to each other in the first horizontal direction (X direction). As used herein, a double-o shape may indicate two “o” shapes joined together, and in some cases may be referred to as or may have the shape of a sideways figure-8, or the shape of an infinity-symbol (or, an ∞ symbol), or the shape of a double-torus. There may be two lobes, or two o's, in such a shape, and a diameter of each o may be the same or similar as, or different from, each other. In some example embodiments, the two lobes or two o's may connect, e.g., may kiss and connect at a single point; alternatively, in some example embodiments, the two lobes or two o's may not connect and may not kiss at a single point. The cylindrical vector beam L02 may have various polarization states by the mode converter 322. The polarization filter 324 may function as a filter that passes components polarized in a specific direction.

As illustrated in FIG. 6, when the cylindrical vector beam L02 has radial polarization, the polarization filter 324 may allow components polarized in the first horizontal direction (e.g., X direction) to pass. The first and second laser beams L10 and L20 filtered by the polarization filter 324 may have polarization components in the direction parallel to the first horizontal direction (X direction).

As illustrated in FIG. 7, when the cylindrical vector beam L02 has azimuthal polarization, the polarization filter 324 may allow components polarized in a direction perpendicular to the first horizontal direction (X direction) to pass. The first and second laser beams L10 and L20 filtered by the polarization filter 324 may have polarization components in the direction perpendicular to the first horizontal direction (X direction).

Referring to FIGS. 8A and 8B, the second beam divider 330 may divide each of the first and second laser beams L10 and L20 divided by the first beam divider 320 into a plurality of laser sub-beams. The second beam divider 330 may be or include a diffractive optical element 332 that may divide the laser beam by using the diffraction phenomenon of the laser beam. The diffractive optical element 332 may have diffraction grating patterns having a grating period. For example, the diffraction grating patterns may each extend in the first horizontal direction (X direction). The diffractive optical element 332 may split the laser beam into 0th to nth diffraction beams (where n is a natural number greater than or equal to 1) according to the diffraction order. Among the Oth to nth diffraction beams, some of the diffraction beams may be used for laser processing. The diffraction beams used for the laser processing may have the same or similar energy intensities.

The second beam divider 330 may further include a position adjustment portion for changing a position of the diffractive optical element 332 in a vertical direction (Z direction) or a rotation angle around an optical axis direction of the diffractive optical element 332. As the position of the diffractive optical element 332 is changed, a spacing distance V2 between the first laser branch beams in the second horizontal direction (Y direction) and a spacing distance V2 between the second laser branch beams in the second horizontal direction (Y direction) may be adjusted. In addition or alternatively, as the rotation angle around the optical axis direction of the diffractive optical element 332 may be varied, the spacing distance or the alignment direction of the branch beams may be adjusted.

As illustrated in FIG. 8A, the second beam divider 330 may divide the incident first laser beam L10 into the plurality of first laser sub-beams L11, L12, L13. The plurality of first laser sub-beams L11, L12, L13 may be spaced apart from each other along the second horizontal direction (Y direction). The plurality of first laser sub-beams L11, L12, L13 may propagate in a plane orthogonal to the first horizontal direction (X direction). For example, the second beam divider 330 may divide the first laser beam L10 into three first laser sub-beams L11, L12, L13. However, it will be understood that the number of the first laser sub-beams is not limited thereto.

As illustrated in FIG. 8B, the second beam divider 330 may divided the incident second laser beam L20 into the plurality of second laser sub-beams L21, L22, L23. The plurality of second laser sub-beams L21, L22, L23 may be spaced apart from each other along the second horizontal direction (Y direction). The plurality of second laser sub-beams L21, L22, L23 may propagate in a plane orthogonal to the first horizontal direction (X direction). For example, the second beam divider 330 may divide the second laser beam L20 into three second laser sub-beams L21, L22, L23. However, it will be understood that the number of the second laser sub-beams is not limited thereto.

The optical modulator 344 may modulate phases of the plurality of first laser sub-beams L11, L12, L13 and the plurality of second laser sub-beams L21, L22, L23 divided by the second beam divider 330. The optical modulator 344 may be or include an electro-optic modulator (EOM). The electro-optic modulator (EOM) may be an optical device capable of modulating a phase of a laser beam according to an applied voltage profile. The optical modulator 344 may spatially control the phase of the laser beam. The optical modulator 344 may change the phase without changing the shape of the waveform. The optical modulator 344 may adjust a wavefront such that the plurality of first laser sub-beams L11, L12, L13 and the plurality of second laser sub-beams L21, L22, L23 may be condensed onto focusing points on a substrate surface by the condensing lens 350.

A plurality of first intermediate laser sub-beams L11′, L12′, L13′ may be obtained from the optical modulator 344 corresponding to the plurality of first laser sub-beams L11, L12, L13. Similarly, a plurality of second intermediate laser sub-beams L21′, L22′, L23′ may be obtained from the optical modulator 344 corresponding to the plurality of second laser sub-beams L21, L22, L23. The wavefronts of the plurality of first intermediate laser sub-beams L11′, L12′, L13′ and the plurality of second intermediate laser sub-beams L21′, L22′, L23′ obtained from the optical modulator 344 may be different from wavefronts of the corresponding plurality of first laser sub-beams L11, L12, L13 and the corresponding plurality of second laser sub-beams L21, L22, L23. Shapes of the plurality of first intermediate laser sub-beams L11′, L12′, L13′ and the plurality of second intermediate laser sub-beams L21′, L22′, L23′ may be the same or similar as the shapes of the corresponding one of the plurality of first laser sub-beams L11, L12, L13, and the plurality of second laser sub-beams L21, L22, L23.

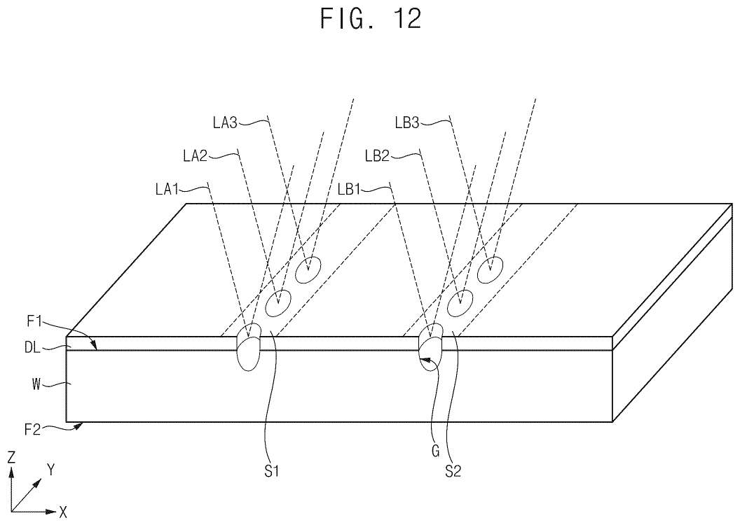

The condensing lens 350 may condense the plurality of first intermediate laser sub-beams L11′, L12′, L13′ into the plurality of first laser branch beams LA1, LA2, LA3 that are then incident on the surface of the substrate, respectively, and may condense the plurality of second intermediate laser sub-beams L21′, L22′, L23′ into the plurality of second laser branch beams LB1, LB2, LB3 that are then incident on the surface of the substrate, respectively. The plurality of first laser branch beams LA1, LA2, LA3 may be focused into spots spaced apart in the first horizontal direction (Y direction) on the surface of the substrate W by the condensing lens 350. The plurality of first laser branch beams LA1, LA2, LA3 may be irradiated in a row on a first scan line S1 (FIG. 11) extending in the second horizontal direction (Y direction). The plurality of second laser branch beams LB1, LB2, LB3 may be focused into spots spaced apart in the first horizontal direction (Y direction) on the surface of the substrate W by the condensing lens 350. The plurality of second laser branch beams LB1, LB2, LB3 may be irradiated in a row on a second scan line S2 (FIG. 11) extending in the second horizontal direction (Y direction).

The condensing lens 350 may be provided in an optical path of the plurality of first intermediate laser sub-beams L11′, L12′, L13′ and the plurality of second intermediate laser sub-beams L21′, L22′, L23′ and may include a single lens optical system having numerical aperture (NA) of at least 0.6. For example, the condensing lens 350 may include the single lens optical system in which a plurality of lenses are sequentially arranged along the optical path. The plurality of first intermediate laser sub-beams L11′, L12′, L13′ and the plurality of second intermediate laser sub-beams L21′, L22′, L23′ may pass through the single lens optical system and may be condensed into the plurality of first laser branch beams LA1, LA2, LA3 and the plurality of second laser branch beams LB1, LB2, LB3, respectively. The plurality of first laser branch beams LA1, LA2, LA3 may correspond to the plurality of second laser branch beams LB1, LB2, LB3, respectively. The first and second laser branch beams corresponding to each other may be spaced apart in the first horizontal direction (X direction). The spacing distance V1 between first and second spots on the substrate W as focus positions of the first and second laser branch beams corresponding to each other may be in a range of 0.5 mm (or about 0.5 mm) to 20 mm (or about 20 mm).

The first and second spots may be local positions where the first and second laser branch beams LA and LB are focused. When the substrate W is a silicon wafer, a plurality of die regions D may be arranged in a matrix shape and divided by scribe lane regions. The number of, and/or the dimensions of, the die regions D is not limited to the illustration in FIG. 1. In some example embodiments, the number of die regions D may be greater than, or less than, that the number illustrated in FIG. 1. In some example embodiments, the die regions D may be rectangular, or may be square, however, example embodiments are not limited thereto. In some example embodiments, the die regions D may be any shape generated by straight lines depending on the singulation method used. In some example embodiments, the die regions D may or may not extend to the edge of the substrate W.

The driving portion of the laser processing apparatus 10 may move the plurality of first laser branch beams LA1, LA2, LA3 and the plurality of second laser branch beams LB1, LB2, LB3 with respect to the substrate W in a second horizontal direction, e.g., perpendicular to, different from the first horizontal direction (X direction) such that the first and second laser branch beams are simultaneously scanned along two scan lines on the substrate W. For example, the second horizontal direction may be a direction (Y direction) perpendicular to the first horizontal direction (X direction).

The stage 20 may be moved in one direction by the stage driver 22 at a scanning speed (such as a dynamically determined speed, or, alternatively, a preset scanning speed). The scanning speed of the first and second laser branch beams LA and LB may be determined by the speed of the stage 20. The scanning speed of the first and second laser branch beams LA and LB may be within a range of 300 mm/s (or about 300 mm/s) to 2000 mm/s (or about 2000 mm/s).

As mentioned above, the laser processing apparatus 10 may include the first beam divider 320 to convert the source laser beam L00 emitted from the laser light source 310 as the single light source into the double-o shaped beam in which a first laser beam L10 and a second laser beam L20 are arranged adjacent to each other in the first horizontal direction (X direction), the second beam divider 330 to divide the first laser beam L10 into the plurality of first laser sub-beams L11, L12, L13 in the second horizontal direction (Y direction) and to divide the second laser beam L20 into the plurality of second laser sub-beams L21, L22, L23 in the second horizontal direction (Y direction), and the condensing lens 350 to condense the plurality of first laser sub-beams and the plurality of second laser sub-beams into the plurality of first laser branch beams LA and the plurality of second laser branch beams LB at the first and second spots spaced apart in the first horizontal direction (X direction) on the surface of the substrate W. In addition, the laser processing apparatus 10 may further include the index adjuster 340 to adjust the spacing distance V1 in the first horizontal direction (X direction) between the first and second spots.

The plurality of first laser branch beams LA and the plurality of second laser branch beams LB may be simultaneously scanned along two scan lines S1, S2 on the substrate W. The distance between the first and second spot positions of the first and second laser branch beams LA and LB may be adjusted according to a size of the die that is to be diced from the wafer. The plurality of first laser branch beams LA and the plurality of second laser branch beams LB may be focused by the single lens optical system.

Accordingly, the plurality of first laser branch beams LA and the plurality of second laser branch beams LB may be simultaneously scanned while tracking a surface height in real time along two adjacent scan lines, with minimal increase in a size of the optical system. Thus, a productivity of the laser grooving process may be improved. Further, the distance V1 between the first laser branch beams LA and the second laser branch beams LB and/or the distance V2 between the constituent first laser branch beams LA and the distance V2 between the constituent second laser branch beams LB may be adjusted optically with relative ease.

Hereinafter, a laser processing method, according to some example embodiments, using the laser processing apparatus 10 of FIG. 1 will be described.

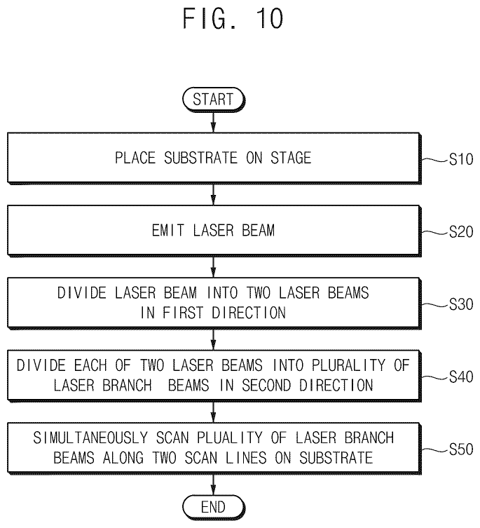

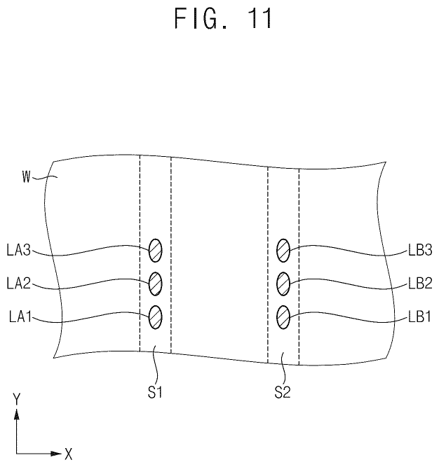

FIG. 10 is a flow chart illustrating a laser processing method, according to some example embodiments. FIG. 11 is a plan view illustrating two scan lines on a wafer along which a plurality of first laser branch beams and a plurality of second laser branch beams are scanned. FIG. 12 is a perspective view illustrating the plurality of first laser branch beams and the plurality of second laser branch beams irradiated along two scan lines in FIG. 11. It is understood that additional operations can be provided before, during, and after the operations in FIG. 10, and some of the operations described below can be replaced or eliminated, for additional example embodiments of the method. The order of the operations/processes may be interchangeable, or two or more operations can be performed simultaneously. In some example embodiments, the method may be performed by the laser processing apparatus 10 of FIG. 1.

Referring to FIGS. 1 to 12, first, a substrate W, which is an object to be processed, may be supported on a stage 20 (operation S10), a laser beam L01 of a cylindrical vector beam may be emitted (operation S20), the cylindrical vector beam L01 may be polarized by a polarization filter 324 to divide the cylindrical vector beam L01 into first and second laser beams L10, L20 in a first horizontal direction (X direction) (operation S30), the first laser beam L10 may be divided into a plurality of first laser sub-beams L11, L12, L13 in a second horizontal direction (Y direction) and the second laser beam L20 may be divided into a plurality of second laser sub-beams L21, L22, L23 in the second horizontal direction (Y direction) (operation S40), and the plurality of first and second laser sub-beams L11, L12, L13, L21, L22, L23 may be condensed onto the substrate W through a condensing lens 350 while scanning along two scan lines S1, S2 (operation S50).

In some example embodiments, after the substrate W is place on a stage 20 of FIG. 1, a source laser beam L00 may be generated by a laser light source 310 as a single light source, and the source laser beam L00 may be converted into the cylindrical vector beam L01 by a mode converter 322. For example, the source laser beam L00 generated by the laser light source 310 may include a Gaussian beam, and the cylindrical vector beam laser L01 converted and emitted by the mode converter 322 may have a donut laser mode.

In some example embodiments, the cylindrical vector beam L01 may be expanded by a beam expander 342 that is provided in an optical path of the cylindrical vector beam L01, to adjust a spacing distance V1 in the first horizontal direction (X direction) between first and second spots where the first and second laser sub-beams are focused, respectively. The laser beam L02 expanded by the beam expander 342 may have a diameter greater than a diameter of the cylindrical vector beam L01.

Then, the polarization filter 324 may polarize the expanded cylindrical vector beam L02 to form the double-o shaped beam in which two beams L10 and L20 are arranged adjacently in the first horizontal direction (X direction). The cylindrical vector beam L02 may have various polarization states by the mode converter 322. The polarization filter 324 may function as a filter that may pass components polarized in a specific direction.

For example, when the cylindrical vector beam L02 has radial polarization, the polarization filter 324 may pass components polarized in the first horizontal direction (X direction). The first and second laser beams L10 and L20 filtered by the polarization filter 324 may have polarization components in the direction parallel to the first horizontal direction (X direction).

Alternatively, when the cylindrical vector beam L02 has azimuthal polarization, the polarization filter 324 may pass components polarized in a direction perpendicular to the first horizontal direction (X direction). The first and second beams L10 and L20 filtered by the polarization filter 324 may have polarization components in the direction perpendicular to the first horizontal direction (X direction).

Then, a second beam divider 330 including a diffractive optical element may divide each of the first and second laser beams L10 and L20 divided by the polarization filter 324 into a plurality of laser sub-beams. For example, the diffraction grating patterns may each extend in the first horizontal direction (X direction). The diffractive optical element 332 may have diffraction grating patterns having a grating period. The diffractive optical element 332 may split the laser beam into Oth to nth diffraction beams (where n is a natural number greater than or equal to 1) according to the diffraction order. Among the Oth to nth diffraction beams, some of the diffraction beams may be used for laser processing.

The second beam divider 330 may divide the incident first laser beam L10 into a plurality of first laser sub-beams L11, L12, L13. The plurality of first laser sub-beams L11, L12, L13 may be spaced apart from each other along the second horizontal direction (Y direction). The plurality of first laser sub-beams L11, L12, L13 may propagate in a plane orthogonal to the first horizontal direction (X direction). For example, the second beam divider 330 may divide the first laser beam L10 into three first laser sub-beams L11, L12, L13. However, it will be understood that the number of the first laser sub-beams is not limited thereto.

The second beam divider 330 may divided the incident second laser beam L20 into a plurality of second laser sub-beams L21, L22, L23. The plurality of second laser sub-beams L21, L22, L23 may be spaced apart from each other along the second horizontal direction (Y direction). The plurality of second laser sub-beams L21, L22, L23 may propagate in a plane orthogonal to the first horizontal direction (X direction). For example, the second beam divider 330 may divide the second laser beam L20 into three second laser sub-beams L21, L22, L23. However, it will be understood that the number of the second laser sub-beams is not limited thereto.

In some example embodiments, phases of the plurality of first laser sub-beams L11, L12, L13 and the plurality of second laser sub-beams L21, L22, L23 may be modulated by an optical modulator 344 that is provided in the optical path of the plurality of first and second laser sub-beams. The optical modulator 344 may include an electro-optic modulator (EOM). The electro-optic modulator (EOM) may be an optical device capable of modulating a phase of a laser beam according to an applied voltage profile. The optical modulator 344 may spatially control the phase of the laser beam. The optical modulator 344 may change the phase with minimal changes to the shape of the waveform.

For example, wavefronts of the plurality of first intermediate laser sub-beams L11′, L12′, L13′ and the plurality of second intermediate laser sub-beams L21′, L22′, L23′ may be changed, while shapes of the plurality of first intermediate laser sub-beams L1l′, L12′, L13′ and the second intermediate laser sub-beams L21′, L22′, L23′ may be maintained.

Then, the condensing lens 350 may condense the plurality of first intermediate laser sub-beams L11′, L12′, L13′ into a plurality of first laser branch beams LA1, LA2, LA3 on the surface of the substrate W, respectively, and may condense the plurality of second intermediate laser sub-beams L21′, L22′, L23′ into a plurality of second laser branch beams

LB1, LB2, LB3 on the surface of the substrate W, respectively. The plurality of first laser branch beams LA1, LA2, LA3 may be focused into spots spaced apart in the first horizontal direction (Y direction) on the surface of the substrate W by the condensing lens 350. The plurality of first laser branch beams LA1, LA2, LA3 may be irradiated in a row on a first scan line S1 extending in the second horizontal direction (Y direction). The plurality of second laser branch beams LB1, LB2, LB3 may be focused into spots spaced apart in the first horizontal direction (Y direction) on the surface of the substrate W by the condensing lens 350. The plurality of second laser branch beams LB1, LB2, LB3 may be irradiated in a row on a second scan line S2 extending in the second horizontal direction (Y direction).

The condensing lens 350 may be provided in an optical path of the plurality of first and second laser sub-beams and may include a single lens optical system having numerical aperture (NA) of at least 0.6. For example, the condensing lens 350 may include the single lens optical system in which a plurality of lenses are sequentially arranged along the optical path. The plurality of first intermediate laser sub-beams L11′, L12′, L13′ and the plurality of second intermediate laser sub-beams L21′, L22′, L23′ may pass through the single lens optical system and are condensed into the plurality of first laser branch beams LA1, LA2, LA3 and the plurality of second laser branch beams LB1, LB2, LB3, respectively. The plurality of first laser branch beams LA1, LA2, LA3 may correspond to the plurality of second laser branch beams LB1, LB2, LB3, respectively. The first and second laser branch beams corresponding to each other may be spaced apart in the first horizontal direction (X direction). The spacing distance V1 between first and second spots on the substrate W as focus positions of the first and second laser branch beams corresponding to each other may be in a range of 0.5 mm (or about 0.5 mm) to 20 mm (or about 20 mm).

Referring to FIGS. 11 and 12, the plurality of first laser branch beams LA1, LA2, LA3 and the plurality of second laser branch beams LB1, LB2, LB3 may be scanned along two scan lines S1 and S2 on the substrate W (operation S50).

The plurality of first laser branch beams LA1, LA2, LA3 and the plurality of second laser branch beams LB1, LB2, LB3 may be moved in in a second horizontal direction, e.g., perpendicular to, different from the first horizontal direction (X direction) relative to the substrate W such that the first and second laser branch beams are simultaneously scanned along two scan lines on the substrate W. For example, the second horizontal direction may be a direction (Y direction) perpendicular to the first horizontal direction (X direction).along two scan lines S1 and S2. Scanning speeds of the plurality of first laser branch beams LA1, LA2, LA3 and the plurality of second laser branch beams LB1, LB2, LB3 may be in a range of 300 mm/s (or about 300 mm/s) to 2000 mm/s (or about 2000 mm/s).

Thus, as illustrated in FIG. 12, grooves G may be formed on a dielectric layer DL deposited on a front surface F1 of the substrate W and on the front surface F1 of the substrate W. The grooves G may be formed by the plurality of first laser branch beams LA1, LA2, LA3 in the first scan line S1, and the grooves G may be formed by the plurality of second branch beams LB1, LB2, LB3 in the second scan line S2.

Through the above processes, the plurality of first and second laser branch beams LA, LB may be continuously or intermittently irradiated while moving relative to the substrate W along the first and second scan lines S1, S2, to perform a laser grooving process. The grooves G may be formed either continuously or intermittently.

The semiconductor package formed by the above-described laser processing apparatus may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

As described herein, any devices, systems, modules, portions, units, controllers, circuits, and/or portions thereof according to any of the example embodiments, and/or any portions thereof (including, without limitation, the controller 40, the laser light source 310, the beam splitter 312, the mode converter 322, the polarization filter 324, the second beam divider 330, the beam expander 342, the optical modulator 344, the condensing lens 350, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), a System-on-Chip (SoC), and programmable logic unit, a microprocessor, application-specific integrated circuit (ASIC), a neural network processing unit (NPU), an Electronic Control Unit (ECU), an Image Signal Processor (ISP), and the like. The processing circuitry may include electrical components such as at least one of transistors, resistors, capacitors, etc. The processing circuitry may include electrical components such as logic gates including at least one of AND gates, OR gates, NAND gates, NOT gates, etc. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

1. A laser processing apparatus, comprising:
a stage configured to support a substrate;
a laser light source configured to generate a source laser beam;
a first beam divider configured to divide the source laser beam into a first laser beam and a second laser beam in a first horizontal direction;
a second beam divider configured to divide the first laser beam into a plurality of first laser sub-beams in a second horizontal direction and to divide the second laser beam into a plurality of second laser sub-beams in the second horizontal direction;
a condensing lens configured to condense the plurality of first laser sub-beams into a plurality of first laser branch beams that are spaced apart along a first scan line on the substrate and to condense the plurality of second laser sub-beams into a plurality of second laser branch beams that are spaced apart along a second scan line parallel with the first scan line on the substrate; and
a driving portion configured to move the plurality of first laser branch beams and the plurality of second laser branch beams relative to the substrate in the second horizontal direction.

2. The laser processing apparatus of claim 1, wherein the first beam divider includes:
a mode converter configured to convert the source laser beam into a cylindrical vector beam; and
a polarization filter configured to polarize the cylindrical vector beam to form a double-o shaped beam in which the first laser beam and the second laser beam are arranged adjacent to each other in the first horizontal direction.

3. The laser processing apparatus of claim 2, wherein the source laser beam includes a Gaussian beam, and the cylindrical vector beam includes a donut laser mode beam.

4. The laser processing apparatus of claim 2, further comprising:
an index adjuster in an optical path of the cylindrical vector beam or in optical paths of the plurality of first laser sub-beams and the plurality of second laser sub-beams,
wherein the index adjuster is configured to adjust a spacing in the first horizontal direction between corresponding ones of the plurality of first laser branch beams and the plurality of second laser branch beams.

5. The laser processing apparatus of claim 4, wherein the index adjuster includes a beam expander in the optical path of the cylindrical vector beam, wherein the beam expander is configured to expand the cylindrical vector beam.

6. The laser processing apparatus of claim 4, wherein the index adjuster includes an electro-optic modulator in the optical paths of the plurality of first laser sub-beams and the plurality of second laser sub-beams.

7. The laser processing apparatus of claim 1, wherein the second horizontal direction is perpendicular to the first horizontal direction.

8. The laser processing apparatus of claim 1, wherein the second beam divider includes a diffractive optical element that is configured to divide the first laser beam and the second laser beam by using diffraction phenomenon of the first laser beam and the second laser beam.

9. The laser processing apparatus of claim 1, wherein a spacing in the first horizontal direction between corresponding laser branch beams of the plurality of first laser branch beams and the plurality of second laser branch beams is in a range of 0.5 mm to 20 mm.

10. The laser processing apparatus of claim 1, wherein the condensing lens is in optical paths of the plurality of first laser sub-beams and the plurality of the second laser sub-beams and includes a single lens optical system having numerical aperture (NA) of 0.6 or more.

11. A laser processing apparatus, comprising:
a stage configured to support a substrate;
a laser irradiator configured to converge and irradiate a plurality of first laser branch beams in a first scan line on the substrate and a plurality of second laser branch beams in a second scan line on the substrate, the first scan line and the second scan line being spaced apart in a first horizontal direction; and
a driving portion configured to move the stage or the laser irradiator and to move the plurality of first laser branch beams and the plurality of second laser branch beams with respect to the substrate in a second horizontal direction different from the first horizontal direction,
wherein the laser irradiator includes:
a laser light source configured to generate a source laser beam;
a mode converter configured to convert the source laser beam into a cylindrical vector beam;
a polarization filter configured to polarize the cylindrical vector beam to form a double-o shaped beam in which a first laser beam and a second laser beam are arranged adjacent to each other in the first horizontal direction;
a diffractive optical element configured to divide the first laser beam into a plurality of first laser sub-beams in the second horizontal direction and to divide the second laser beam into a plurality of second laser sub-beams in the second horizontal direction; and
a condensing lens in optical paths of the plurality of first laser sub-beams and the plurality of second laser sub-beams, the condensing lens being configured to condense the plurality of first laser sub-beams into the plurality of first laser branch beams and condense the plurality of second laser sub-beams into the plurality of second laser branch beams on the substrate.

12. The laser processing apparatus of claim 11, wherein the source laser beam includes a Gaussian beam, and the cylindrical vector beam includes a donut laser mode beam.

13. The laser processing apparatus of claim 11, wherein, when the cylindrical vector beam has radial polarization, the polarization filter is configured to pass components polarized in a direction parallel to the first horizontal direction in response to the cylindrical vector beam having radial polarization.

14. The laser processing apparatus according to claim 11, wherein, when the cylindrical vector beam has azimuthal polarization, the polarization filter is configured to pass components polarized in a direction perpendicular to the first horizontal direction in response to the cylindrical vector beam having azimuthal polarization.

15. The laser processing apparatus of claim 11, wherein the second horizontal direction is perpendicular to the first horizontal direction.

16. The laser processing apparatus of claim 11, further comprising:
an index adjuster in an optical path of the cylindrical vector beam or in the optical paths of the plurality of first laser sub-beams and the plurality of second laser sub-beams, wherein the index adjuster is configured to adjust a spacing in the first horizontal direction between corresponding ones of the plurality of first laser branch beams and the plurality of second laser branch beams.

17. The laser processing apparatus of claim 16, wherein the index adjuster includes a beam expander in the optical path of the cylindrical vector beam and configured to expand the cylindrical vector beam.

18. The laser processing apparatus of claim 16, wherein the index adjuster includes an electro-optic modulator in the optical paths of the plurality of first laser sub-beams and the plurality of second laser sub-beams.

19. The laser processing apparatus of claim 11, wherein a spacing in the first horizontal direction between the plurality of first laser branch beams and the plurality of second laser branch beams that correspond to each other is in a range of 0.5 mm to 20 mm.

20. The laser processing apparatus of claim 11, wherein the condensing lens is in the optical paths of the plurality of first laser sub-beams and the plurality of second laser sub-beams and includes a single lens optical system having numerical aperture (NA) of 0.6 or more.

21-30. (canceled)
